(19) United States
(12) Patent Application Publication
(10) Pub. No.: US 2018/0040772 A1
(43) Pub. Date: Feb. 8, 2018

(54) OPTOELECTRONIC SEMICONDUCTOR BODY AND METHOD OF PRODUCING AN OPTOELECTRONIC SEMICONDUCTOR BODY

(71) Applicant: OSRAM Opto Semiconductors GmbH, Regensburg (DE)

(72) Inventor: Andreas Rudolph, Regensburg (DE)

(21) Appl. No.: 15/556,381

(22) PCT Filed: Mar. 9, 2016
(86) PCT No.: PCT/EP2016/055045

§ 371 Date: Sep. 7, 2017

(30) Foreign Application Priority Data
Mar. 19, 2015 (DE) 10 2015 104 144.8

(51) Int. Cl. H01L 33/40; H01L 33/38; H01L 33/44; H01L 31/18; H01L 31/0304; H01L 31/0224; H01L 31/0216; H01L 33/30; H01L 33/00

(52) U.S. Cl. CPC H01L 33/40; H01L 33/30; H01L 33/382; H01L 33/44; H01L 33/0062; H01L 33/0066; H01L 31/03046; H01L 31/022408; H01L 31/02161; H01L 31/184; H01L 31/1852

(57) ABSTRACT

An optoelectronic semiconductor body includes a carrier, a semiconductor layer sequence having a first layer of a first conductivity type, a second layer of a second conductivity type and an active layer, wherein the first layer faces the carrier and the active layer generates or absorbs electromagnetic radiation when operated in its intended operation mode, and at least one through-via extending from the carrier right through the first layer and the active layer and at least partly through the second layer, wherein, when in operation, second charge carriers are injected via the through-via into the second layer, in a region of the active layer and the first layer the through-via is completely surrounded laterally by a continuous and contiguous bed of the active layer and the first layer, the through-via is formed from a semiconductor material, and the carrier is a growth substrate for the semiconductor layer sequence.

### TECHNICAL FIELD

This disclosure relates to an optoelectronic semiconductor body and a method of producing an optoelectronic semiconductor body.

### BACKGROUND

It could be helpful to provide a semiconductor body with through-vias in which no or reduced migration or inward diffusion of metals occurs from the through-vias into the semiconductor layer sequence. It could also be helpful to provide an efficient and inexpensive method of producing such a semiconductor body.

### SUMMARY

I provide an optoelectronic semiconductor body including a carrier, a semiconductor layer sequence applied to the carrier and having a first layer of a first conductivity type, a second layer of a second conductivity type and an active layer arranged between the first layer and the second layer, wherein the first layer faces the carrier and the active layer generates or absorbs electromagnetic radiation when operated in its intended operation mode, and at least one through-via extending from the carrier right through the first layer and the active layer and at least partly through the second layer, wherein, when in operation, second charge carriers are injected via the through-via into the second layer, in a region of the active layer and the first layer the through-via is completely surrounded laterally by a continuous and contiguous bed of the active layer and the first layer, the through-via is formed from a semiconductor material, and the carrier is a growth substrate for the semiconductor layer sequence.

I also provide a method of producing an optoelectronic semiconductor body including A) providing a growth substrate having a major side; B) applying at least one catalyst droplet to the major side of the growth substrate; C) growing a first semiconductor material under first growth conditions, wherein, under the first growth conditions, in a region of the catalyst droplet stronger layer growth takes place in the direction away from the major side than in a region to the sides of the catalyst droplet and semiconductor wires thus arise; D) growing a passivation layer under second growth conditions, wherein, under the second growth conditions, growth of the passivation layer occurs on a circumferential surface of the semiconductor wire extending transversely of the major side; E) growing a third semiconductor material under third growth conditions, wherein, under the third growth conditions, in the region of the catalyst droplet stronger layer growth takes place in the direction away from the major side than in the region to the sides of the catalyst droplet and in this way the semiconductor wire is lengthened; and F) growing a semiconductor layer sequence onto the major side of the growth substrate under fourth growth conditions, wherein, first a first layer of a first conductivity type, than an active layer and thereafter a second layer of a second conductivity type are grown in succession, wherein the semiconductor layer sequence grows in the region next to the semiconductor wire and the first layer and also the active layer laterally completely surround the semiconductor wire such that the semiconductor wire extends from the growth substrate right through the first layer and the active layer and at least partly through the second layer.

### BRIEF DESCRIPTION OF THE DRAWINGS

FIGS. 1 and 2 are cross-sectional views of an optoelectronic semiconductor body.

FIGS. 3A to 4C show, in cross-sectional view, method steps of producing an optoelectronic semiconductor body.

### LIST OF REFERENCE SIGNS

1 Semiconductor layer sequence
2 Through-via
3 Passivation layer
4 Catalyst droplets
5 Insulation layer
10 First layer
11 Active layer
12 Second layer
13 Carrier
14 Radiation entrance or radiation exit face
20 Semiconductor wire
21 Circumferential surface
30 Protective layer
100 Semiconductor body

### DETAILED DESCRIPTION

The optoelectronic semiconductor body may comprise a carrier. A semiconductor layer sequence is arranged on the carrier, having a first layer of a first conductivity type, a second layer of a second conductivity type and an active layer arranged between the first layer and the second layer. The first layer faces the carrier, and the second layer is remote from the carrier. When operated in its intended operation mode, the active layer generates or absorbs electromagnetic radiation. The layer of the first conductivity type comprise a p-doped layer, for example, configured for hole transport. The second layer of the second conductivity type is, for example, an n-doped layer configured to transport electrons. The first and second layers may each be n-doped or p-doped.

The first and/or second layer may in this respect in particular also each be understood to be a layer sequence consisting of a plurality of individual layers. For example, the first layer comprises all the semiconductor layers between a first major side of the semiconductor layer sequence and the active layer. The second layer may, for example, comprise all the layers between a second major side, opposite the first major side, of the semiconductor layer sequence and the active layer.

The semiconductor layer sequence is based, for example, on a III-V compound semiconductor material. The semiconductor material, for example, comprises a nitride compound semiconductor material such as AlₙIn₁₋ₙ₋ₘGaₘN, or a phosphide compound semiconductor material such as AlₙIn₁₋ₙ₋ₘGaₘP or indeed an arsenide compound semiconductor material such as AlₙIn₁₋ₙ₋ₘGaₘAs, wherein in each case 0≦n≦1, 0≦m≦1 and m+n≦1. The semiconductor layer sequence may comprise dopants and additional constituents. For simplicity's sake, however, only the essential constituents of the crystal lattice of the semiconductor layer sequence are indicated, i.e., Al, As, Ga, In, N or P, even if these may in part be replaced and/or supplemented by small quantities of further substances. The semiconductor layer sequence is preferably based on AlInGaN or AlInGaAs.

The active layer of the semiconductor layer sequence in particular contains at least one pn junction and/or a quantum well structure in the form of an individual quantum well, or SQW for short, or in the form of a multiple quantum well structure, or MQW for short.

Radiation generated by the active layer when in operation lies in particular in the region of the spectrum between 400 nm and 940 nm.

The optoelectronic semiconductor body may comprise at least one through-via that extends from the carrier right through the first layer and the active layer. The through-via additionally extends at least partly through the second layer. In particular, the through-via opens in the second layer.

Second charge carriers may be injected via the through-via into the second layer when the semiconductor body is in operation. The second charge carriers may correspond to the conductivity type of the second layer. There is in particular direct electrical contact between the through-via and the second layer such that the second charge carriers may arrive directly from the through-via into the second layer without detours and without having previously to pass through any further layers.

In the region of the active layer and the first layer, the through-via may be completely surrounded laterally by a continuous and contiguous bed of the active layer and the first layer. The lateral direction is in this respect a direction parallel to a main direction of extension of the semiconductor layer sequence. In plan view onto the semiconductor layer sequence, in a sectional view along the active layer, the through-via is thus completely surrounded, without interruption, by the active layer, while in a sectional view parallel to the first layer the through-via is completely surrounded, without interruption, by the first layer.

The through-vias may comprise a semiconductor material or are formed therefrom or consist thereof. Charge carrier electrical conduction within the through-via thus preferably takes place via a semiconductor material. The semiconductor material may be one of the above-stated semiconductor materials, in particular GaAs. The semiconductor material of the through-via may be doped or undoped.

The carrier to which the semiconductor layer sequence has been applied may be at the same time the growth substrate for the semiconductor layer sequence. The carrier may, for example, likewise comprise or consist of one of the above-stated semiconductor materials. In particular, the carrier comprises or consists of silicon or GaAs or GaN or SiC or sapphire. Alternatively, however, it is also possible for the growth substrate to have been detached from the semiconductor body and for the carrier to be an auxiliary carrier other than the growth substrate applied afterwards, comprising or consisting, for example, of a metal or semiconductor material.

The optoelectronic semiconductor body may comprise a carrier and a semiconductor layer sequence applied to the carrier having a first layer of a first conductivity type, a second layer of a second conductivity type and an active layer arranged between the first layer and the second layer, wherein the first layer faces the carrier and wherein the active layer generates or absorbs electromagnetic radiation when operated in its intended operation mode. In addition, the semiconductor body comprises at least one through-via extending from the carrier right through the first layer and the active layer and at least partly through the second layer. When the semiconductor body is in operation, second charge carriers are injected via the through-via into the second layer. In this respect, in the region of the active layer and the first layer the through-via is completely surrounded laterally by a continuous and contiguous bed of the active layer and the first layer. Furthermore, the through-via is formed of a semiconductor material. The carrier is, for example, the growth substrate for the semiconductor layer sequence.

In conventional semiconductor chips with through-vias, the through-vias are metallic. The result of this may be that the metal migrates or inwardly diffuses from the through-vias into the semiconductor layer sequence and in the process changes the conductivity and optical characteristics of the semiconductor layer sequence. Moreover, production of semiconductor bodies with metallic through-vias is associated with relatively major effort since, in these cases, the growth substrate cannot itself be used as the carrier, but rather an auxiliary carrier has to be applied after introduction of the through-vias.

In the semiconductor body described here, the through-vias are formed from a semiconductor material, whereby no or reduced inward diffusion of metals occurs from the through-vias into the semiconductor layer sequence. Furthermore, as demonstrated below, such a semiconductor body may be produced particularly efficiently and inexpensively. In particular, there is in this case no need to detach the growth substrate and use an auxiliary carrier.

The through-via may comprise a circumferential surface extending transversely of a main direction of extension of the semiconductor layer sequence. The through-via may then, for example, be cylindrical or rod-shaped, wherein the main direction of extension of the rod or the axis of symmetry of the cylinder extends transversely of or perpendicular to the main direction of extension of the semiconductor layer sequence.

In the region of the first layer and of the active layer the circumferential surface may be surrounded completely and without interruption by a passivation layer. The passivation layer in this case preferably prevents a direct current flow between the through-via and the first layer or between the through-via and the active layer when in operation. The passivation layer is thus in particular poorly electrically conductive or insulating. Poorly conductive means, for example, that the passivation layer has a conductivity at least 100 times or 10000 times or 1000000 times less than the conductivity within the through-via.

In the region of the second layer the circumferential surface may be at least partly free of the passivation layer. In particular, at least 50% or at least 60% or at least 70% or at least 99% of the part of the circumferential surface arranged in the region of the second layer is free of the passivation layer. Preferably, therefore, not only is a bottom face of the through-via but also a part of the circumferential surface free of the passivation layer. The bottom face of the through-via is in this respect a boundary face of the through-via remote from the carrier and extending substantially parallel to the main direction of extension of the semiconductor layer sequence.

The passivation layer may comprise a semiconductor material, for example, one of the above-stated semiconductor materials, in particular an undoped semiconductor material such as undoped AlGaAs, or consists thereof or is formed therefrom.

The through-via may extend through the entire semiconductor layer sequence, i.e., in particular the second layer may also be completely passed through by the through-via. The bottom face of the through-via may preferably terminate flush with one surface, for example, the second major side of the semiconductor layer sequence or projects beyond the semiconductor layer sequence in the direction away from the carrier.

The through-via may open into the second layer and end within the second layer. The second layer may preferably be a highly doped current spreading layer. The highly doped current spreading layer here in particular comprises a high lateral electrical conductivity, whereby charge carriers injected into the current spreading layer via the through-via, are distributed efficiently along the semiconductor layer sequence. The lateral electrical conductivity within the current spreading layer amounts, for example, to at least 1000/(Ω·m) or 10000/(Ω·m) or 100000/(Ω·m).

The carrier may mechanically support and stabilize the semiconductor layer sequence. Preferably, no further, auxiliary carrier is needed or present for mechanical stabilization of the semiconductor body in addition to the carrier, which is particularly preferably at the same time the growth substrate.

A side of the semiconductor layer sequence remote from the carrier may be a radiation exit face or radiation entrance face of the semiconductor body. When in operation, the radiation generated in the active layer is coupled out of the semiconductor body via the radiation exit face while, when in operation, radiation is coupled into the semiconductor body via the radiation entrance face and absorbed by the active layer and, for example, converted into an electronic signal.

The through-via may be in direct mechanical and electrical contact with the carrier and electrically conductively connects directly to the carrier. In particular, no further layers are located between the through-via and the carrier. Charge carriers may, for example, pass directly and without detours from the carrier into the through-via without, for example, having to pass through further layers.

When in operation, the second charge carriers may be injected via the carrier and via the through-via into the second layer. An electrical contact may, for example, be mounted on the carrier, via which the second charge carriers are injected into the carrier and passed on via the carrier into the through-via.

An insulation layer may be arranged between the first layer and the carrier in the region to the sides of the through-via. In plan view onto the semiconductor layer sequence, the through-via is then, for example, completely surrounded by a contiguous bed of the insulation layer. The insulation layer is configured in particular to prevent direct electrical contact between the first layer and the carrier. To this end, the insulation layer preferably has poor conductivity or is of insulating configuration.

The insulation layer and the passivation layer may be formed from the same material and form a contiguous and one-piece layer. The insulation layer and the passivation layer are thus in particular one and the same layer.

The carrier may have the same type of doping as the through-via. For example, the through-via and the carrier are both n-doped.

The through-via may have a width or a diameter measured parallel to the active layer of at least 30 nm or 50 nm or 70 nm. Alternatively or in addition, the width or the diameter of the through-via is at most 500 nm or 400 nm or 300 nm. The axial length of the through-vias transversely of the main direction of extension of the semiconductor layer sequence amounts, for example, to at least 500 nm or 1 μm or 2 μm. Alternatively or in addition, the axial length of the through-vias amounts to at most 7 μm or 5 μm or 4 μm.

A surface coverage density of the through-vias within the semiconductor layer sequence amounts, for example, to at least 0.0001% or 0.001% or 0.01%. Alternatively or in addition, the surface coverage density is at most 2% or 1% or 0.1%.

A method of producing an optoelectronic semiconductor body is additionally provided. The method is suitable in particular for producing an optoelectronic semiconductor body described here. In other words, all features disclosed in relation to the optoelectronic semiconductor body are also disclosed for the method and vice versa.

The method may comprise a step A, in which a growth substrate having a major side is provided.

In a subsequent step B, a catalyst droplet or, preferably, a plurality of catalyst droplets is/are applied to the major side of the growth substrate.

In a subsequent step C, a first semiconductor material is grown onto the growth substrate under first growth conditions. The first growth conditions are preferably selected such that, in the region of the catalyst droplet, stronger layer growth takes place in the direction away from the major side than in the region to the sides of the catalyst droplet and in this way a semi-conductor wire arises in the region of the catalyst droplet. For the first growth conditions, a temperature for the growth substrate of 400° C. to 620° C. is selected, for example. A method of growing semiconductor wires with the assistance of catalyst droplets is known, for example, from “Wurtzite to Zinc Blende Phase Transition in GaAs Nanowires Induced by Epitaxial Burying” by Gilles Patriarche et al., Nano Letters Vol. 8, No. 6, 1638-1643, 2008. Patriarche describes vapor-liquid-solid growth, or VLS for short. Catalytically acting liquid alloy droplets are used in this case. When reaction gases are introduced to form the semiconductor layer sequence, these are absorbed at the surface of the catalyst droplet and diffuse through the surface. Due to supersaturation at the interface of the liquid droplet with the underlying substrate and the surface to be patterned, accelerated crystal growth arises, resulting in semiconductor wires.

In a step D a passivation layer, preferably in the form of a second semiconductor material, is grown under second growth conditions, wherein under the second growth conditions growth of the passivation layer occurs on a circumferential surface of the semiconductor wire extending transversely of the major side. In this case, preferably no or less, in particular very much less growth of the passivation layer takes place in the axial direction of the semiconductor wires. This may be achieved, for example, in that under the second growth conditions the temperature of the growth substrate is decreased such that the catalyst droplet hardens. In this way, the reaction gases flowing in for formation of the passivation layer can no longer diffuse through the catalyst droplet and growth under the catalyst droplet does not occur.

In a step E, a third semiconductor material is grown under third growth conditions, wherein, under the third growth conditions, in the region of the catalyst droplet stronger layer growth again takes place in the direction away from the major side than in the region to the sides of the catalyst droplet and in this way the semiconductor wire is lengthened, until it has reached a predetermined target length. Under the third growth conditions the growth substrate temperature is, for example, again selected such that the catalyst droplet is liquid and diffusion of the reaction gases through the catalyst droplet is possible.

In a step F, a semiconductor layer sequence is grown onto the major side of the growth substrate under fourth growth conditions, wherein firstly a first layer of a first conductivity type, then an active layer and thereafter a second layer of a second conductivity type are grown in succession. In the process, the semiconductor layer sequence preferably grows in the region next to the semiconductor wire such that the first layer and also the active layer laterally completely surround the semiconductor wire. The fourth growth conditions are preferably selected such that growth of the semiconductor layer sequence is stronger to the sides of the semiconductor wire than on the semiconductor wire. To this end, for example, the temperature of the growth substrate may be set correspondingly high, for example, the temperature of the growth substrate then amounts to more than 600° C.

The growth substrate, the first, second and third semiconductor materials and the semiconductor layer sequence may, for example, be or comprise one of the above-stated semiconductor materials or consist thereof.

Growth of the semiconductor wire and the semiconductor layer sequence is preferably performed in a reaction chamber using metal-organic vapor phase epitaxy, or MOVPE for short.

Steps A to F may be performed mutually independently and in succession in the stated sequence.

Steps C and E may be performed in succession and prior to step D. The semiconductor wire is thus first grown to its complete target length, without a passivation layer being applied.

In step D, the passivation layer is then preferably applied to the circumferential surface of the semiconductor wire, in particular to the entire circumferential surface of the semiconductor wire such that the semiconductor wire is lateral completely surrounded on all sides by the passivation layer.

After step D and prior to step F, a protective layer is then, for example, applied to the major side of the growth substrate, which protective layer covers and encloses the semiconductor wire laterally up to a specified height. In a subsequent step, for example, an etching method is used to remove the passivation layer preferably completely from the semiconductor wire in the regions of the semiconductor wire not covered by the protective layer.

Then, the protective layer may be removed again, for example. What then remains is a semiconductor wire completely sheathed by a passivation layer up to the specified height viewed from the substrate. The predetermined height is preferably selected such that the active layer to be applied later does not project beyond the passivation layer in the direction away from the growth substrate.

The catalyst droplet comprises or consists of Au or Ga or a mixture thereof. To apply the catalyst droplet, a lithographic method may, for example, be used in step B. For example, in step B a mask layer, for example, an SiO₂ layer may be applied to the growth substrate and then patterned using a lithographic method such that holes are produced in the mask layer in which the growth substrate is uncovered. Growth of the semiconductor layer sequence may then be started, for example, with a gallium excess as a result of which gallium droplets form within the holes that then act as catalyst droplets. The SiO₂ layer is then preferably removed again.

If gold is used as the material for the catalyst droplets, first, a layer of gold may be applied to the growth substrate, for example. Then, regions of the gold layer are etched away such that gold dots remain on the growth substrate and the gold dots are then heated. Au/Ga catalyst droplets are formed therefrom, under which the semiconductor wires grow.

In step D, regions on the major side of the growth substrate to the sides of the semiconductor wire are also covered by the passivation layer. The passivation layer on the circumferential surface of the semiconductor wire and on the major face of the growth substrate then preferably forms a contiguous, continuous and one-piece passivation layer which, when the semiconductor body is in operation, prevents direct electrical contact of the growth substrate and/or of the semiconductor wire with the first layer and/or the active layer.

Once the target length for the semiconductor wire has been reached in step E, the catalyst droplet is removed. This may, for example, be achieved by a wet or dry chemical etching method. If Ga catalyst droplets are used, all that is needed to remove the catalyst droplets is to switch off the Ga flow while increasing arsenic pressure.

In step F, the semiconductor layer sequence is grown to such a height that the semiconductor layer sequence projects beyond the semiconductor wire in the direction away from the major side of the growth substrate and the semiconductor wire terminates in the region of the second layer.

In step F, the semiconductor layer sequence is grown only to such a height that the semiconductor wire projects beyond the semiconductor layer sequence in the direction away from the major side of the growth substrate. Only then, for example, are the catalyst droplet and a remainder of the semiconductor wire projecting beyond the semiconductor layer sequence removed.

An optoelectronic semiconductor body described here and a method of producing an optoelectronic semiconductor body are explained in greater detail below on the basis of examples and with reference to the drawings. Elements that are the same in the individual figures are indicated with the same reference numerals. The relationships between the elements are not shown to scale, however, but rather individual elements may be shown exaggeratedly large to assist in understanding.

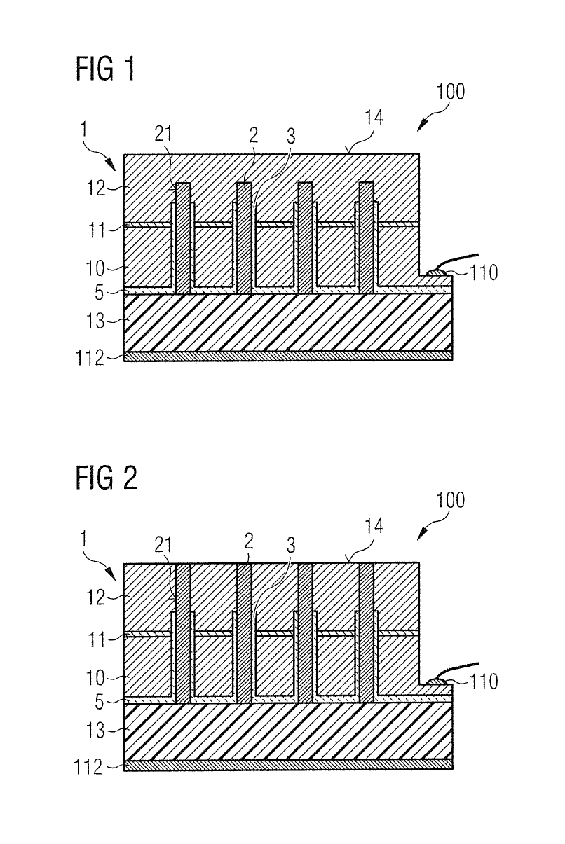

FIG. 1 shows an optoelectronic semiconductor body 100 in cross-sectional view. In this case, a semiconductor layer sequence 1 has been applied to a carrier 13, having a first layer 10 of a first conductivity type facing the carrier 13 and a second layer 12 of a second conductivity type remote from the carrier 13. Between the first layer 10 and the second layer 12 an active layer 11 is arranged that generates or absorbs electromagnetic radiation when the semiconductor body 100 is being operated in its intended operation mode. In this case, the semiconductor layer sequence 1 is based, for example, on AlGaAs. In addition, the carrier 13 is here the growth substrate for the semiconductor layer sequence 1 and formed for this purpose, for example, from GaAs or silicon.

The first layer 10 is, for example, a p-doped layer with holes as charge carriers, while the second layer 12 is, for example, an n-doped layer with electrons as charge carriers. The carrier 13 may likewise be n-doped and electrically conductive. It is alternatively also possible, however, for the first layer 10 to be n-doped and the second layer 12 and the carrier 13 to be p-doped.

Starting from the carrier 13, through-vias 2 extend through the first layer 10 and the active layer 11 and open in the second layer 12. The through-vias 2 are in direct mechanical and electrical contact with the carrier 13. Charge carriers, for example, electrons may be injected via a contact element 112 on the backface of the carrier 13 into the carrier 13, flow directly and without detours from the carrier 13 into the through-vias 2, and be injected via the through-vias 2 directly into the second layer 12.

The through-vias 2 of FIG. 1 comprise a circumferential surface 21 extending transversely of a main direction of extension of the semiconductor layer sequence. In this case, the through-vias 2 take the form of rods, for example, with a main direction of extension perpendicular to or transversely of the main direction of extension of the semiconductor layer sequence 1. The circumferential surface 21 of the through-via 2 is here covered at least in part with a passivation layer 3. The passivation layer 3 here completely encloses the circumferential surfaces 21 in the region of the first layer 10 and the active layer 11 such that charge carriers from the through-via 2 cannot directly enter the active layer 11 or the first layer 10. The passivation layer 3 thus forms insulation for the through-vias 2.

In the region of the second layer 12, the circumferential surfaces 21 of the through-vias 2 are at least partly, here at least 50%, free of the passivation layer 3. In these free regions of the circumferential surfaces 21 the charge carriers are then able to pass from the through-via 2 directly into the second layer 12.

In this case, the through-vias 2 comprise or consist of a semiconductor material, for example, GaAs. In particular, the through-vias 2 are provided with the same type of doping as the carrier 13 and/or the second layer 12. The width of the through-vias 2 parallel to the main direction of extension of the semiconductor layer sequence 1 amounts, for example, to 50 nm to 100 nm. The passivation layer 3 is likewise based, for example, on a semiconductor material such as AlGaAs and is preferably undoped. Alternatively, however, the passivation layer may also consist of SiO₂.

In addition, between the first layer 10 and the carrier 13, in the region to the sides of the through-vias 2, an insulation layer 5 is applied, which prevents direct electrical contact between the first layer 10 and the carrier 13. The insulation layer 5 thus ensures that charge carriers fed into the carrier 13 cannot penetrate directly into the first layer 10. The insulation layer 5 and the passivation layer 3 are preferably of continuous and one-piece configuration and consist of the same material. In other words, the insulation layer 5 and the passivation layer 3 are thus one and the same layer, which is introduced into the semiconductor body 100, for example, in a single method step.

In a peripheral region of the semiconductor body 100 the second layer 12 and the active layer 11 have been removed in places. In this region a further contact element 110, which serves in electrical contacting of the first layer 10, is applied to a subarea, remote from the carrier 13, of the first layer 10.

Overall, therefore, when the semiconductor body 100 is in operation first charge carriers may, for example, be fed via the further contact element 110 into the first layer 10 and then enter the active layer 11. Second charge carriers are introduced via the contact element 112 into the carrier 13, flow from there directly into the through-vias 2 and are then injected into the second layer 12, whence the second charge carriers likewise enter the active layer 11. In the active layer 11 the first charge carriers and the second charge carriers may then recombine with one another, wherein electromagnetic radiation is generated, preferably in the visible range. The radiation generated may then pass out of the semiconductor body 100 via a radiation exit face 14 of the semiconductor body 100 remote from the carrier 13.

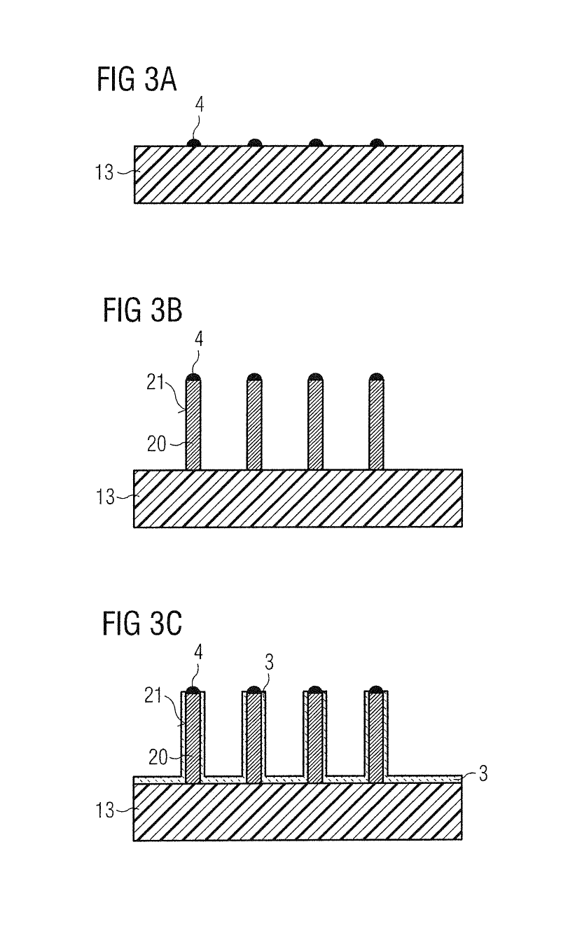

The example of FIG. 2 shows a similar semiconductor body 100 to FIG. 1. Unlike in FIG. 1, however, the through-vias 2 here extend through the entire semiconductor layer sequence 1, in particular also through the entire second layer 12. The through-vias 2 in this case terminate flush with the semiconductor layer sequence 1 on a side remote from the carrier 13. In this case, the circumferential surfaces 21 of the through-vias 2 are at least 70% free of the passivation layer 3 in the region of the second layer 12.

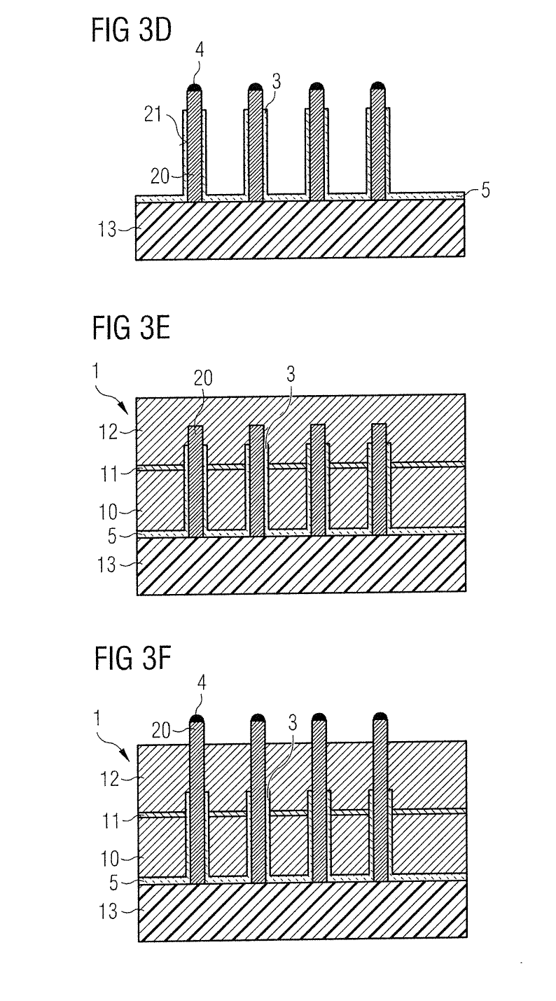

The example of FIG. 3A shows a first method step of producing the semiconductor body 100. In this case, catalyst droplets 4 have been applied to a major side of a growth substrate 13. The catalyst droplets 4, for example, comprise or consist of Ga or Au/Ga. In particular, the catalyst droplets 4 may be applied to the growth substrate 13 using a lithographic method. The mask necessary for the lithographic method has already been removed in the example of FIG. 3A.

FIG. 3B shows a next method step, in which the growth substrate 13 of FIG. 3A has been introduced, for example, into a reaction chamber, for example, for metal-organic vapor phase epitaxy, or MOVPE for short, and reaction gases such as gallium and arsenic have been introduced. As a result of introduction of the reaction gases, a first semiconductor material in the form of semiconductor wires, which are then based, for example, on GaAs grows under the catalyst droplets 4. In this case, first growth conditions are selected such that growth takes place predominantly under the catalyst droplets 4, while to the sides of the catalyst droplets 4 growth of the semiconductor material is strongly suppressed. In this case, growth takes place, for example, at a temperature of the growth substrate 13 of at least 400° C.

In the example of FIG. 3C, a next method step is shown in which, under second growth conditions, a second semiconductor material is grown in the form of a passivation layer 3 onto the circumferential surfaces 21 of the semiconductor wires 20. The passivation layer 3 then completely covers the circumferential surfaces 21 of the semiconductor wires 20. Furthermore, the passivation layer 3 grows on the major side of the growth substrate 13 in the region to the sides of the semiconductor wires 20 and completely covers the major side of the growth substrate 13 in these regions. The second growth conditions are in this case selected such that growth of the passivation layer 3 is strongly suppressed or does not take place under the catalyst droplets 4 on the semiconductor wires 20. To this end, the growth temperature of the growth substrate 13 may be reduced, for example, such that the catalyst droplets 4 harden and no diffusion of the reaction gases takes place through the catalyst droplets 4.

The passivation layer 3 in the example of FIG. 3C, for example, contains undoped AlGaAs and/or SiO₂ or consists thereof.

In the example of FIG. 3D, a further method step is shown, wherein a third semiconductor material is grown onto the growth substrate 13 under third growth conditions. In this case, the growth conditions are again selected such that growth of the third semiconductor material takes place predominantly in the region of the catalyst droplets 4, whereby the semiconductor wires 20 are extended until they reach their target length. This may again be achieved by selecting high growth temperatures. Growth of the third semiconductor material in the region to the sides of the semiconductor wires 20 is strongly suppressed in this case.

In the example of FIG. 3E the catalyst droplets 4 have been removed, for example, using a wet chemical etching process or by switching off a gallium flow while increasing arsenic pressure. After removal of the catalyst droplets 4, a semiconductor layer sequence 1 is applied under fourth growth conditions. In this case, first of all a first layer 10 of a first conductivity type is applied to the major side of the growth substrate 13, then an active layer 11 and thereupon a second layer 12 of a second conductivity type. After application of the semiconductor layer sequence 1, the semiconductor wires 20 are laterally completely surrounded by the first layer 10, the active layer 11 and the second layer 12. Furthermore, the semiconductor wires 20 extend as far as into the second layer 12 and open or end in the second layer 12. The fourth growth conditions, for example, involve bringing the temperature of the growth substrate to over 600° C. such that growth of the semiconductor layer sequence 1 is strengthened in the region to the sides of the semiconductor wires 20, while growth on the semiconductor wires 20 is suppressed.

The production method described may also be identified from the finished component. As demonstrated in “Wurtzite to Zinc Blende Phase Transition in GaAs Nanowires Induced by Epitaxial Burying” by Gilles Patriarche et al., Nano Letters Vol. 8, No. 6, 1638-1643, 2008, the semiconductor wires 20 may, as soon as they are surrounded by the semiconductor layer sequence 1, adopt the lattice structure, for example, zinc blende structure, of the semiconductor layer sequence 1. Regions of the semiconductor wires 20 not surrounded by the semiconductor layer sequence 1 may, in contrast, have other lattice structures, for example, a Wurtzite lattice structure. As a result of the subsequent growth of the semiconductor layer sequence 1 laterally around the semiconductor wires 20, lattice structure adaptation of the semiconductor wires 20 may thus occur, which may be identified, for example, using a transmission electron microscope, or TEM for short.

The example in FIG. 3F shows an alternative to FIG. 3E. Here, the semiconductor wires 20 have grown taller than in the example of FIG. 3E and, therefore, have a greater target length. Once the semiconductor layer sequence 1 has been grown, the semiconductor wires 20 project beyond the semiconductor layer sequence 1 in a direction away from the carrier 13. Furthermore, the catalyst droplets 4 remain on the semiconductor wires 20. In a next step the protruding semiconductor wires 20 and the catalyst droplets 4 may then be removed such that the semiconductor wires 20 terminate flush with the second layer 12 in a direction away from the carrier 13.

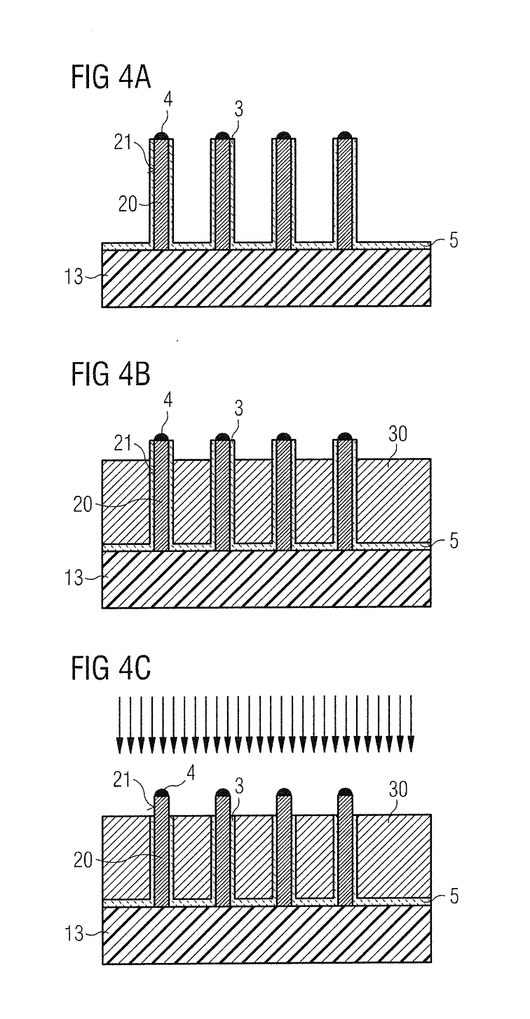

FIGS. 4A to 4C show an alternative to the growth described above of the semiconductor wires 20.

In FIG. 4A the semiconductor wires 20 have already been grown up to their target length. Once the semiconductor wires 20 have grown, the passivation layer 3 is applied to the circumferential surfaces 21 of the semiconductor wires 20. In this case, the passivation layer 3 again completely covers the circumferential surfaces 21 of the semiconductor wires 20.

Then, in the example of FIG. 4B, a protective layer 30 is applied to the major side of the growth substrate 13 up to a predeterminable height. The protective layer 30 is applied only to such a height that the semiconductor wires 20 continue to project beyond the protective layer 30 in the direction away from the carrier 13.

In the example of FIG. 4C, a wet chemical or dry chemical etching method is then used, for example, to remove the passivation layer 3 from the circumferential surfaces 21 of the semiconductor wires 20 in the regions of the semiconductor wires 20 not protected by the protective layer 30. In this way, the circumferential surfaces 21 of the semiconductor wires 20 are exposed in places. In the region of the protective layer 30, the passivation layer 3 preferably remains completely on the circumferential surfaces 21 of the semiconductor wires 20. After the etching method, the protective layer 30 can then be removed again such that the same or a similar structure of semiconductor wires 20 as shown in FIG. 3D remains. From this point, the same method steps as described in relation to FIG. 3E may be applied.

The description made with reference to examples does not restrict this disclosure to these examples. Rather, the disclosure encompasses any novel feature and any combination of features, including in particular any combination of features in the appended claims, even if the features or combination is not itself explicitly indicated in the claims or examples.

This application claims priority of DE 10 2015 104 144.8, the subject matter of which is incorporated herein by reference.

1-16. (canceled)

17. An optoelectronic semiconductor body comprising:
a carrier,
a semiconductor layer sequence applied to the carrier and having a first layer of a first conductivity type, a second layer of a second conductivity type and an active layer arranged between the first layer and the second layer, wherein the first layer faces the carrier and the active layer generates or absorbs electromagnetic radiation when operated in its intended operation mode, and
at least one through-via extending from the carrier right through the first layer and the active layer and at least partly through the second layer, wherein,
when in operation, second charge carriers are injected via the through-via into the second layer,
in a region of the active layer and the first layer the through-via is completely surrounded laterally by a continuous and contiguous bed of the active layer and the first layer,
the through-via is formed from a semiconductor material, and
the carrier is a growth substrate for the semiconductor layer sequence.

18. The optoelectronic semiconductor body according to claim 17,
wherein the through-via comprises a circumferential surface extending transversely of a main direction of extension of the semiconductor layer sequence,
in the region of the first layer and of the active layer the circumferential surface is surrounded completely and without interruption by a passivation layer,
the passivation layer prevents both a direct current flow between the through-via and the first layer and between the through-via and the active layer when in operation,
in the region of the second layer the circumferential surface is at least partly free of the passivation layer, and
the passivation layer is formed from a semiconductor material.

19. The optoelectronic semiconductor body according to claim 17, wherein the through-via extends through the entire semiconductor layer sequence.

20. The optoelectronic semiconductor body according to claim 17,
wherein the through-via opens into the second layer, and
the second layer is a highly doped current spreading layer.

21. The optoelectronic semiconductor body according to claim 17,
wherein the carrier mechanically supports and stabilizes the semiconductor layer sequence, and
a side of the semiconductor layer sequence remote from the carrier forms a radiation exit or radiation entrance face of the semiconductor body.

22. The optoelectronic semiconductor body according to claim 17,
wherein the through-via and the carrier are directly electrically conductively connected to one another, and
in operation the second charge carriers are injected via the carrier and via the through-via into the second layer.

23. The optoelectronic semiconductor body according to claim 17,
wherein an insulation layer is arranged between the first layer and the carrier in the region next to the through-via,
the insulation layer prevents direct electrical contact between the first layer and the carrier, and
the insulation layer and the passivation layer are formed from the same material and form a contiguous and one-piece layer.

24. The optoelectronic semiconductor body according to claim 17,
wherein the passivation layer is formed from an undoped semiconductor material, and
the carrier has the same type of doping as the through-via.

25. The optoelectronic semiconductor body according to claim 17,
wherein the through-via has a width measured parallel to the active layer of 50 nm to 120 nm,
the through-via comprises GaAs,
the carrier comprises silicon and/or GaAs, and
the passivation layer comprises AlGaAs.

26. A method of producing an optoelectronic semiconductor body comprising:
A) providing a growth substrate having a major side;
B) applying at least one catalyst droplet to the major side of the growth substrate;
C) growing a first semiconductor material under first growth conditions, wherein, under the first growth conditions, in a region of the catalyst droplet stronger layer growth takes place in the direction away from the major side than in a region to the sides of the catalyst droplet and semiconductor wires thus arise;
D) growing a passivation layer under second growth conditions, wherein, under the second growth conditions, growth of the passivation layer occurs on a circumferential surface of the semiconductor wire extending transversely of the major side;
E) growing a third semiconductor material under third growth conditions, wherein, under the third growth conditions, in the region of the catalyst droplet stronger layer growth takes place in the direction away from the major side than in the region to the sides of the catalyst droplet and in this way the semiconductor wire is lengthened; and
F) growing a semiconductor layer sequence onto the major side of the growth substrate under fourth growth conditions, wherein, first a first layer of a first conductivity type, then an active layer and thereafter a second layer of a second conductivity type are grown in succession, wherein the semiconductor layer sequence grows in the region next to the semiconductor wire and the first layer and also the active layer laterally completely surround the semiconductor wire such that the semiconductor wire extends from the growth substrate right through the first layer and the active layer and at least partly through the second layer.

27. The method according to claim 26, wherein steps A) to F) are performed mutually independently and in succession.

28. The method according to claim 26,
wherein steps C) and E) are performed in succession and prior to step D),
in step D), the passivation layer is applied to the circumferential surface of the semiconductor wire,
after step D) and prior to step F), a protective layer is applied to the major side of the growth substrate that laterally covers and encloses the semiconductor wire up to a specified height, and
removing the passivation layer by an etching method from the semiconductor wire in the region of the semiconductor wire not covered by the protective layer.

29. The method according to claim 26,
wherein the catalyst droplet comprises Au or Ga or a mixture thereof, and
in step B), a lithographic method is used to apply the catalyst droplet.

30. The method according to claim 26,
wherein, in step D), regions on the major side of the growth substrate laterally next to the semiconductor wire are also covered by the passivation layer, and
the passivation layer forms a continuous, contiguous and one-piece layer which, when the semiconductor body is in operation, prevents direct electrical contact between growth substrate and semiconductor wire and the first layer and the active layer.

31. The method according to claim 26,
wherein once a target length for the semiconductor wire has been reached in step E), the catalyst droplet is removed, and
in step F, the semiconductor layer sequence is grown to such a height that the semiconductor layer sequence projects beyond the semiconductor wire in the direction away from the major side of the growth substrate and the semiconductor wire terminates in the region of the second layer.

32. The method according to claim 26,
wherein, in step F), the semiconductor layer sequence is grown only to such a height that the semiconductor wire projects beyond the semiconductor layer sequence in the direction away from the major side of the growth substrate, and
removing the catalyst droplet and a remainder of the semiconductor wire protruding beyond the semiconductor layer sequence.
